(19) United States
(12) Patent Application Publication
(10) Pub. No.: US 2019/0020160 A1
(43) Pub. Date: Jan. 17, 2019

(54) ELECTRICAL CONNECTOR

(71) Applicant: REFLEX S.r.l., Guiglia (Modena) (IT)

(72) Inventors: Roberto Rabacchi, Guiglia (Moderna) (IT); Renzo Gibellini, Castelfranco Emilia (Modena) (IT)

(21) Appl. No.: 15/750,490

(22) PCT Filed: Aug. 3, 2016
(86) PCT No.: PCT/IB2016/054670

§ 371 Date: Feb. 5, 2018

(30) Foreign Application Priority Data
Aug. 4, 2015 (IT) 102015000041710

(51) Int. Cl. H01R 31/06; B60D 1/64; H01R 13/66; H01R 12/52; H01R 12/58; H05K 3/36

(52) U.S. Cl. CPC H01R 31/065; B60D 1/64; H01R 13/6658; H01R 12/7082; H01R 12/58; H05K 3/368; H05K 2201/10295; H01R 12/523

(57) ABSTRACT

An electrical connector (10) comprising a plurality of pins (11) arranged according to a first arrangement and connectable to a respective series of cables. A first circuit board (12) forms a first series of electrical paths (17), each of which is electrically connected to a respective pin (11). A second circuit board (13) forms a second series of electrical paths (17). An electric terminal (16) is fastened to the second circuit board (13), the terminal having a plurality of electrical contacts (18) arranged according to a second arrangement, and configured for receiving respective cables. Each contact (18) of the terminal (16) is directly connected to a respective one of the electrical paths (17) of the second circuit board (13). Electrically conductive interconnection pins (14) are each connected to a respective conductive path (17) of the first board (12) and to a respective conductive path (17) of the second board (13), so as to electrically connect each pin (11) to a respective electrical contact (18) of the terminal (16).

### TECHNICAL FIELD

The present invention relates to an electrical connector. The electrical connector is particularly, but not exclusively, suitable for connecting cables between a trailer and a tractor of a trailer vehicle.

### PRIOR ART

There are known electrical connectors in which a plurality of cables is connected manually to a plurality of pins arranged in a substantially circular arrangement or on two or more concentric circumferences. At the present time, there are no automatic machines capable of performing this operation. The manual performance of this task causes a considerable loss of time, since the cables have to be connected manually, one by one, to the respective pins in a predetermined order.

This manual operation is highly labour-intensive and increases the overall production cost of the aforesaid electrical connectors. Furthermore, with a manual operation there is a high probability of making an incorrect connection, which may cause subsequent damage to the connector itself or to an apparatus to which the connector is connected.

A further limitation of the prior art connectors is that they are designed purely for the purpose of putting a plurality of cables into contact with the respective plurality of pins, without any possibility of executing further functions, for example the quality control of the signals passing through the connector, in an independent way.

### BRIEF DESCRIPTION OF THE INVENTION

One object of the present invention is therefore to provide an electrical connector which can speed up the connecting operation and enable it to be automated, thus improving the connector manufacturing process. Another object of the invention is to provide an opportunity for executing other functions such as the quality control of the signals passing through the connector pins.

These and other objects and advantages, which will become more apparent from the following text, are achieved with an electrical connector whose main features are defined in claim 1. Specific embodiments of the invention are set forth in the dependent claims, the content of which is to be considered as an integral part of the present description.

Briefly, an electrical connector according to the present invention comprises a plurality of pins arranged according to a particular arrangement, for example a circular arrangement, and connectable to a respective plurality of cables. The connector incorporates a first circuit board that forms a first series of electrical paths, each of which is electrically connected to a respective pin. A second circuit board forms a second plurality of electrical paths. An electric terminal is fastened to the second circuit board, the terminal having a plurality of electrical contacts arranged according to a second arrangement and configured for receiving respective cables. Each contact of the terminal is directly connected to a respective one of the electrical paths of the second circuit board. Electrically conductive interconnection pins are each connected to a respective conductive path of the first circuit board and to a respective conductive path of the second board, so as to electrically connect each pin to a respective electrical contact of the terminal.

The aforesaid arrangement makes it possible to change from a circular or concentric geometric arrangement of the pins to a linear arrangement of the electrical contacts of the terminal.

The connector speeds up the connecting operation and enables it to be automated, and may provide other functions such as the quality control of the signals passing through the connector pins.

It is also possible to install electronic components on the board in order to provide the connector with additional functions. Thus, the connector becomes a connecting element capable of performing analyses and operations on the signals transmitted through the pins.

### BRIEF DESCRIPTION OF THE DRAWINGS

Further features and advantages of the present invention will be apparent from the following detailed description, provided purely by way of non-limiting example, with reference to the attached drawings, in which:

FIG. 1 is an exploded perspective view of the electrical connector according to an embodiment of the invention;

FIG. 2 is a side view of the electrical connector of FIG. 1;

FIG. 3 is a view in axial section of a body of the connector housing the electrical connector of FIG. 1;

FIGS. 4A and 4B are a front view and a rear view, respectively, of the electrical connector of FIG. 1;

FIG. 5 shows an exemplary perspective view of the electrical connector in which electronic components are installed; and

FIGS. 6 and 7 are, respectively, a perspective view and a side view of a pin.

### DETAILED DESCRIPTION

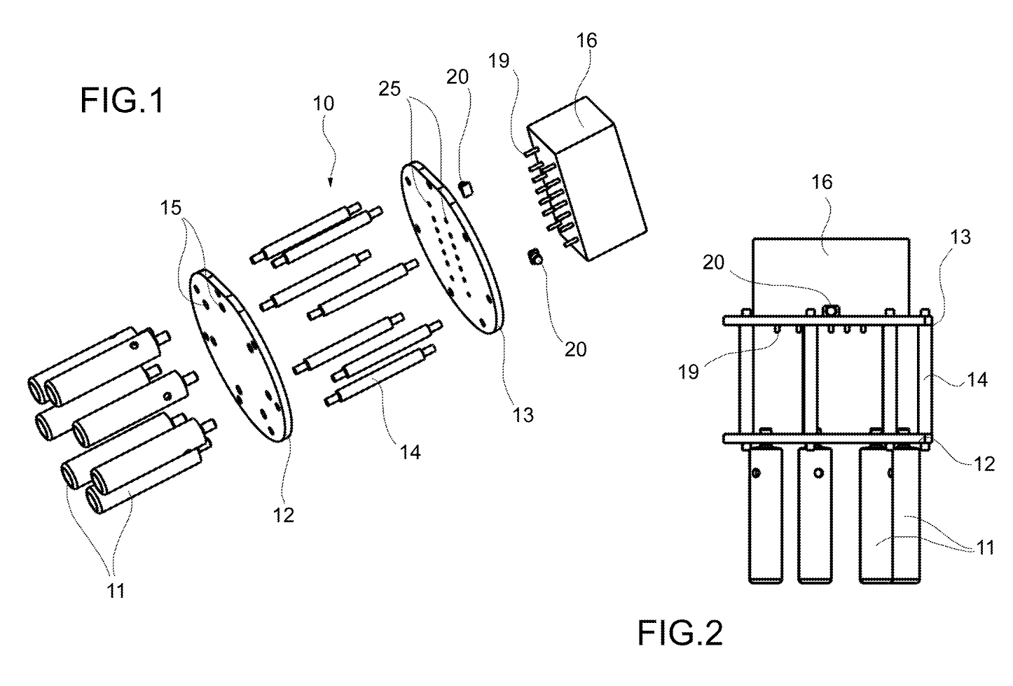

Referring initially to FIG. 1, the number 10 indicates the whole of an electrical connector according to an embodiment of the invention. The connector 10 has a plurality of pins 11 arranged according to a first arrangement, in this example a substantially circular arrangement. Each of the pins 11 is to be connected to a respective cable belonging to a plurality of cables (not shown).

In the illustrated embodiment, the connector 10 comprises two circuit boards 12, 13, mechanically and electrically connected by coupling means 14 of electrically conductive material.

In the illustrated embodiment, the coupling means of electrically conductive material comprises metal interconnection pins 14.

Preferably, the metal interconnection pins 14 extend parallel to a longitudinal direction. As interpreted herein, terms and expressions indicating directions such as “transverse”, “longitudinal” and “axial” are to be interpreted with reference to the (longitudinal) direction in which the pins 11 extend.

The first board 12 may accommodate the plurality of pins 11 arranged according to a first, substantially circular arrangement. The first board 12 has a plurality of through holes 15, arranged in the substantially circular arrangement, and each adapted to receive a respective pin, as explained below.

The signals received and/or transmitted by the plurality of pins 11 are passed to the second board 13 through the interconnection pins 14.

An electric terminal 16 having a plurality of electrical contacts 18 is installed on the second board 13.

The second board 13 has electrical paths 17 for connecting each of the interconnection pins 14 to a respective electrical contact 18 of the terminal 16.

In an alternative embodiment (not shown), a row or array of terminals aligned in a transverse direction could be used instead of a single terminal 16.

The electrical contacts 18 are arranged according to a second arrangement, in this example a substantially linear arrangement, and are intended to be connected in turn, in a per se known manner, to a respective plurality of cables (not shown). Numeral 19 designates electrical connection studs of the terminal 16 which are connected to the electrical paths by means of through holes 25 for electrical connection arranged on the circuit board 13. The studs 19 may have an arrangement corresponding to that of the electrical contacts 18 located on the opposite side of the terminal 16.

Advantageously, electronic components 23 may be installed on any of the circuit boards 12, 13, these components being capable, for example, of monitoring the presence and the quality of signals transmitted and/or received by the pins 11, and of signalling, by means of a notification to the user, any absence or insufficient quality of said signals. The notification may be provided by means of a message sent on a CAN bus, radio messages, or visual signals directly visible on the electrical connector 10.

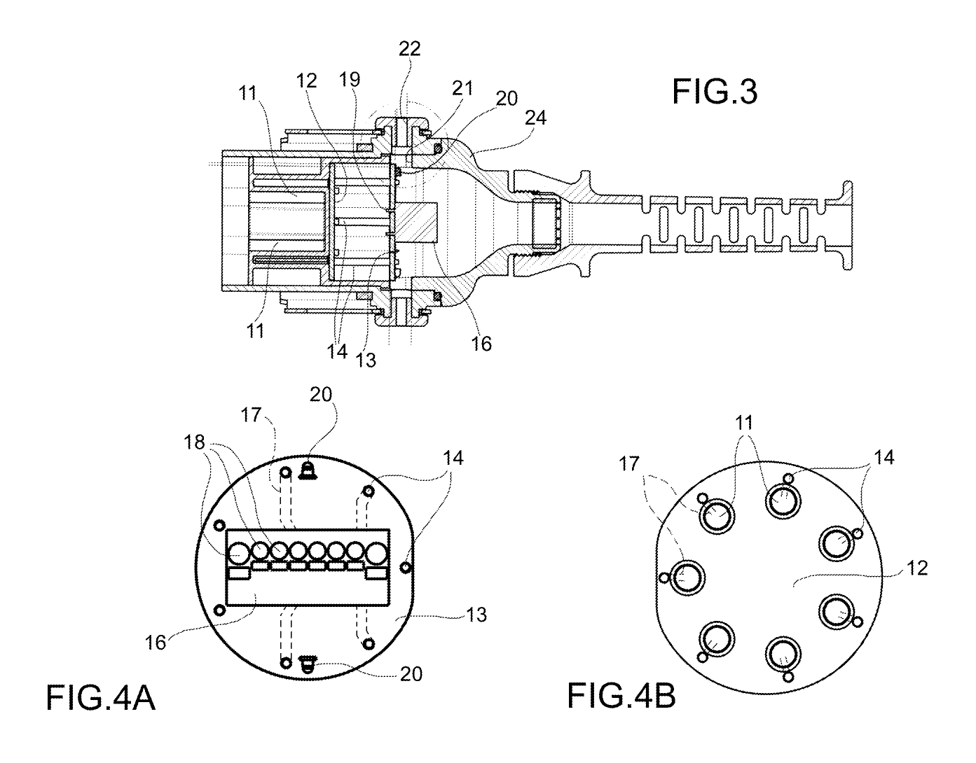

The visual signals emitted by the electrical connector 10 may, for example, be emitted by means of LED lights 20 (FIG. 3) and illuminated lines which are also visible from outside the body 24 of the connector.

According to an embodiment, as shown in FIG. 3, a casing or sleeve 24 for containing the connector 10 may have one or more radial apertures 21 opening near an LED 20 affixed to the board 13. In the particular example of FIG. 3, a light guide 22 is inserted into the aperture 21.

If the signals are sent by messages on a CAN bus or by radio messages, these messages may be subsequently processed by other control units present on the vehicle or by external diagnostic devices.

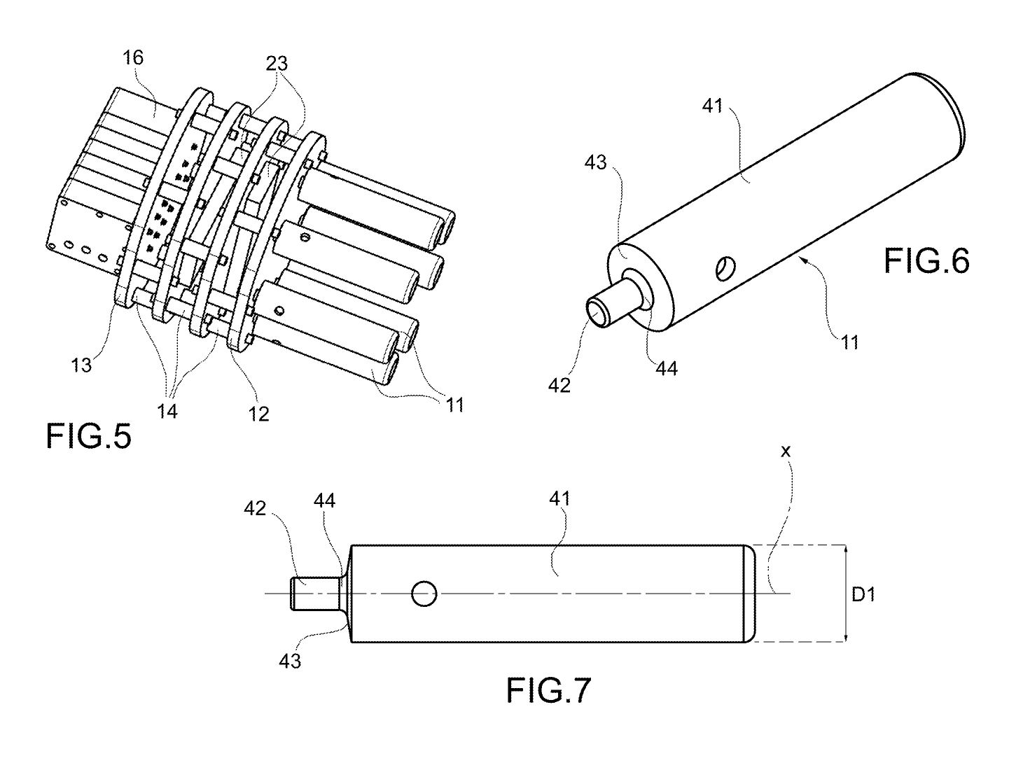

FIG. 5 shows a perspective view of an example of a connector having a plurality of boards, on some of which electronic components 23 are installed.

In contrast to the example shown in FIGS. 1 to 5, the electric terminal 16 may, in another embodiment of the invention, have electrical contacts 18 arranged in a circular arrangement substantially similar to, or corresponding to, the arrangement of the pins 11, with identical or different diameters.

FIGS. 6 and 7 show a perspective view and a side view of a single pin 11. The pin 11 has a main body 41 of cylindrical shape, elongated in a longitudinal direction and having a given diameter D1. The pin has a terminal appendage 42 which extends from one end 43 of the main body 41 and has a transverse dimension smaller than the diameter D1 of the main body.

The appendage 42 is configured to be inserted into one of the holes 15 formed in the circuit board 12 and subsequently welded to the board 12 so as to electrically connect the pin 11 to a path 17 integral with the board.

The appendage 42 extends longitudinally along a geometric axis substantially coincident with, or parallel to, the central geometric axis x along which the main body 41 of the pin extends.

According to another embodiment which is not shown, the appendage 42 may be inclined or offset with respect to the central geometric axis x.

The transverse dimension of the appendage 42 may range between about ½ and about ⅙ of the diameter D1 of the main body 41 of the pin. Preferably, the transverse dimension of the appendage 42 substantially corresponds to the diameter of one of the holes 15, so that the appendage 42 can easily be inserted through the hole 15 and welded therein.

This appendage 42 extends from one (43) of the ends of the main body 41, which may advantageously have a slightly conical surface, tapered towards the appendage 42. The conical surface forms an angle A of between about 0° and about 45° with respect to a geometrical plane perpendicular to said longitudinal direction.

The appendage 42 has a radiused root portion 44 for connection to the conical surface of the end 43 of the main body 41.

This type of pin 11 may be used equally well as either a male or a female pin. The only differences will be found in the shape of the main body 41. The pin 11 shown by way of example in FIGS. 6 and 7 is a female connector.

Although the pin 11 has been described herein in combination with the electrical connector 10, it is to be understood that a pin having the features discussed herein above may also be used in electrical connections of different types.

Advantageously, the electronic connector according to the invention can speed up the connection operation performed manually by personnel and can enable it to be automated, and, as well as providing a simple connection of a plurality of cables to the respective plurality of pins, may also provide other functions, such as the quality control of the signals passing through the connector.

Various aspects and embodiments of the connector and the pin have been described. It is to be understood that each embodiment may be combined with any other embodiment. Furthermore, the invention is not limited to the embodiments described, but may be modified within the scope defined by the attached claims.

1. An electrical connector comprising:
a plurality of pins arranged according to a first arrangement and connectable to a respective plurality of cables;
at least a first circuit board, comprising at least one layer of electrically conductive material that forms a plurality of electrical paths, each path being electrically connected to a respective pin;
characterized in that the connector further comprises:
at least a second circuit board, comprising at least one layer of electrically conductive material that forms a plurality of electrical paths;
at least one electric terminal, fixed to the second circuit board, the terminal having a plurality of electrical contacts which are arranged according to a second arrangement and are configured for receiving respective cables or electric conductors, wherein each contact of the terminal is directly connected to a respective one of the electrical paths of the second circuit board;
a plurality of electrically conductive couplings, each connected to a respective one of the conductive paths of the first circuit board and to a respective one of the conductive paths of the second circuit board, so as to electrically connect each pin to a respective electrical contact of the terminal.

2. A connector according to claim 1, wherein the second arrangement of the electrical contacts of the terminal is substantially identical to, or corresponds to, the first arrangement of the pins.

3. A connector according to claim 1, wherein the second arrangement of the electrical contacts of the terminal is different from the first arrangement of the pins.

4. A connector according to claim 3, wherein the first arrangement of the pins is a substantially circular arrangement, and wherein the second arrangement of the electrical contacts of the terminal is a linear arrangement.

5. A connector according to claim 1, further comprising one or more electronic components installed on the circuit board.

6. A connector according to claim 5, wherein at least one of the electronic components installed on the circuit board is a component for monitoring the presence and the quality of signals transmitted and/or received by the pins and for generating a notification indicating the absence or insufficient quality of said signals.

7. A connector according to claim 5, wherein the notification consists of a message sent on the Controller Area Network (CAN bus), radio messages, or a visual signal directly visible on the electrical connector.

8. A connector according to claim 5, wherein at least one electronic component associated with at least one circuit board comprises at least one LED light adapted to emit a visual signal indicating the absence or insufficient quality of signals transmitted and/or received by the pins.

9. A connector according to claim 1, wherein the electrically conductive couplings comprise metal interconnection pins mechanically and electrically connecting the first and second circuit boards.

10. A connector according to claim 1, wherein each pin has
a main body of cylindrical shape elongated in a longitudinal direction and having a given diameter,
a terminal appendage which extends from one end of the main body and has a transverse dimension smaller than the diameter of the main body, the appendage being adapted to be inserted into a hole formed in a circuit board and subsequently welded to the board so as to electrically connect the pin to a path integral with the board.

11. A connector according to claim 10, wherein the appendage extends longitudinally along a geometric axis substantially coincident with a central geometric axis along which the main body of the pin extends.

12. A connector according to claim 10, wherein the transverse dimension of the appendage ranges between about ½ and about ⅙ of the diameter of the main body of the pin.

13. A connector according to claim 10, wherein the appendage extends from a terminal face located at one end of the main body and having a shape of a conical surface tapered towards the appendage.

14. A connector according to claim 13, wherein the conical surface forms an angle of between about 0° and about 45° with respect to a geometrical plane perpendicular to said longitudinal direction.

15. A connector according to claim 10, wherein the appendage has a radiused root portion for connection to the conical surface of the main body.

16. A connector according to claim 3, wherein the first arrangement of the pins is arranged in one or more concentric circles, and wherein the second arrangement of the electrical contacts of the terminal is a linear arrangement.
